(19) United States
(12) Patent Application Publication
(10) Pub. No.: US 2012/0247531 A1
(43) Pub. Date: Oct. 4, 2012

(54) FLUORINATED ANTIREFLECTIVE COATING

(75) Inventors: SUDIP MUKHOPADHYAY, BERKELEY, CA (US); DAVID NALEWAJEK, WEST SENECA, NY (US)

(73) Assignee: HONEYWELL INTERNATIONAL INC., MORRISTOWN, NJ (US)

(21) Appl. No.: 13/073,615

(22) Filed: Mar. 28, 2011

(51) Int. Cl. H01L 31/052; B32B 27/00; B05D 3/02; B05D 3/00; B05D 1/28; C09D 127/12; B05D 5/06

(52) U.S. Cl. 136/246; 524/546; 428/421; 427/164

(57) ABSTRACT

Anti-reflective coatings and coating solutions, optically transparent elements and improved processes for preparing AR coatings and coating solutions are described. The anti-reflective coatings are formed from a fluoropolymer derived from at least one fluoropropene compound. The fluoropolymer may applied as a coating solution that is curable at low temperatures.

### TECHNICAL FIELD

The invention relates generally to anti-reflective coatings for optically transparent elements and more particularly to anti-reflective fluoropolymer coatings for glass covers used in photovoltaic cell applications.

### BACKGROUND

Anti-reflective (AR) coatings are used in several industries, including in the manufacture of photovoltaic (PV) modules, to reduce the reflection fraction of incident light as light passes through an optically transparent element such as glass. The goal of AR coatings is to achieve a refractive index that is as close to 1.23 as possible to maximize light transmission over a broad band of light wavelengths.

Coating optically transparent elements with one or more layers of a low refractive index coating can achieve improved transmittance in a broad wavelength range and a wide range of incident angles. Such coatings have been deposited onto glass protective covers as sol-gel materials by conventional coating techniques, and have been reported to improve solar light transmittance by about two to three percent in the visible portion of the light spectrum. However, AR coatings formed from such coatings have a cure temperature (600° C.-700° C.) that may be too high for certain substrates, including plastic substrates and glass substrates used in applications where glass cannot be subjected to tempering temperatures.

### SUMMARY

Embodiments disclosed herein pertain to AR coatings and coating solutions, optically sensitive elements such as photovoltaic modules that employ AR coatings, and improved processes for preparing AR coatings and coating solutions.

One embodiment is an optically transparent element including an optically transparent substrate and an AR coating disposed on a portion (e.g. part or all) of at least one surface of the optically transparent substrate. The AR coating includes at least one fluoropolymer represented by the following formula:

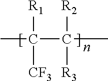

wherein n=10 to 2500, R₁, R₂ and R₃ are each selected from H and F and the polymer has a molecular weight between 2000 and 200,000. Another embodiment is a photovoltaic module including at least one optically transparent element described above.

A further embodiment provides a method of producing a fluoropolymer by polymerizing a compound represented by the formula CF₃CR₁═CR₂R₃, wherein R₁, R₂ and R₃ are each selected from H and F, in the presence of at least one initiator in a reaction solution and extracting the resulting fluoropolymer from the reaction solution. Another embodiment provides an AR coating solution including the fluoropolymer shown and described above dispersed or dissolved in at least one solvent.

An embodiment also provides a method of forming an optically transparent element by applying the AR coating solution onto an optically transparent substrate and curing. Curing may be performed at a temperature of less than 350° C., more particularly at no more than 300° C.

### BRIEF DESCRIPTION OF THE FIGURES

FIG. 1 is a flow chart of a method of producing an optically transparent element including an AR coating in accordance with an embodiment of the invention.

FIG. 2 provides a schematic illustration of a photovoltaic cell including an AR coating in accordance with an embodiment of the invention.

FIG. 3 is a chart showing the out-gas properties of an exemplary embodiment.

### DETAILED DESCRIPTION

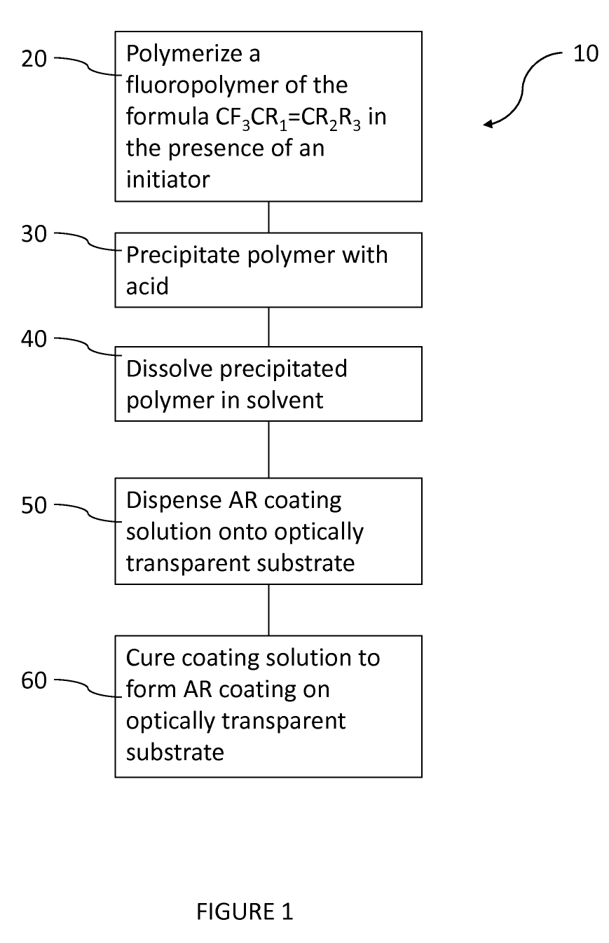

FIG. 1 is a flow chart illustrating a method 10 of forming an AR coating solution and an optically transparent element according to one embodiment. According to the method 10, an AR coating solution is formed by polymerizing a fluorocarbon compound of the general formula CF₃CR₁═CR₂R₃ in the presence of an initiator and under suitable reaction conditions (Block 20). The resulting polymer is represented by the following formula:

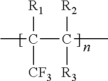

wherein n=10-2500, R₁, R₂ and R₃ are each selected from H and F and the polymer has a molecular weight between 2000 and 200,000 daltons. After forming the polymer, acid may be added to precipitate the polymer (Block 30). The precipitated polymer may then be filtered, dried and combined with another solvent to form an AR coating solution (Block 40). The AR coating solution is then applied to an optically transparent substrate (Block 50) and cured to form an optically transparent element (Block 60) which may be used in photovoltaic cell applications.

A variety of commercially available hydrofluoro-olefins or (“HFOs”) may be used to form the fluoropolymer. Suitable HFOs may have the general formula CF₃CR₁═CR₂R₃, wherein R₁, R₂ and R₃ are each selected from H and F. Examples of suitable HFOs include tetrafluoropropene compounds and pentafluoropropene compounds. A particularly suitable tetrafluoropropene compound is 2,3,3,3-tetrafluoro-1-propene (HFO-1234yf), which forms a polymer having the following formula:

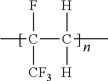

wherein n=10-2500.

Other suitable tetrafluoropropene compounds include HFO-1234zf and HFO-1234ze. Suitable pentafluoropropene compounds include HFO-1225. Stereoisomers of any of the foregoing compounds may also be suitable.

In one embodiment, the compounds referenced above may be-copolymerized with additional monomer compounds, and in particular with additional fluorocarbon compounds. Suitable additional fluorocarbon compounds include straight chain fluorocarbon compounds such as vinylidene fluoride, trifluoroethylene, tetrafluoromethylene and fluoropropene. In other embodiments, the method is carried out without the addition of other monomers such that a homopolymer is formed.

Polymerization is carried out in the presence of one or more free-radical initiators. Suitable initiators include azobiscyanoacrylates, aliphatic peresters such as t-butyl peroctoate and t-amyl peroctoate, aliphatic peroxides such as tert-butyl peroxide, aliphatic hydroperoxides such as tert-butyl hydroperoxide, persulfates such as sodium persulfate, potassium persulfate, ammonium persulfate and iron persulfate, and combinations of the foregoing. A persulfate initiator may be particularly suitable for the present invention. The initiator may be included in the reaction solution at a concentration of less than 20 wt %, more particularly less than 12 wt % and even more particularly less than 1.0 wt % based on the total weight of the monomer.

The reaction between the polymer and initiator may be carried out in a solution including water, buffer, and/or a surfactant. Suitable buffers include Na₂HPO₄, NaH₂PO₄, FeSO₄ and combinations. Particularly suitable buffers include sodium phosphate dibasic heptahydrate, sodium phosphate monobasic, ferrous sulfate heptahydrate and combinations thereof. Suitable surfactants include fluorosurfactants, more particularly perfluorinated carboxylic acid surfactants such as C₅HF₁₅O₂ and C₇F₁₅CO₂(NH₄). Reducing agents such as Na₂S₂O₅ and additional solvents/diluents may also be added.

The reaction may be carried out in, for example, an autoclave or jacketed stirred tank reactor (STR) via a batch or semi-batch mode at a temperature of between 20° C. and 85° C., more particularly, between about 40° C. and about 60° C. Reaction times may range from 30 minutes to about 48 hours, more particularly, from about 10 to about 24 hours. The resulting polymer may have a molecular weight between about 2000 and 200,000 daltons, more particularly, between about 15,000 to about 100,000 daltons.

In one embodiment, a minor amount of peroxide as a finishing step may be added after the polymerization reaction has substantially ended. Such a finishing step has the purpose of removing minor amounts of unreacted monomers and aids. After completing polymerization, the polymer is precipitated from the emulsion by adding acid. The polymer precipitate is then filtered and dried.

An AR coating solution is then formed by dissolving or dispersing the polymer in a suitable organic solvent. Suitable organic solvents generally include, for example, acetone, methyl acetate, ethyl acetate and various ketone solvents. The AR coating solution may also contain various additives such as surfactants commercially available from BYK, for example.

The AR coating solution is then applied on at least a portion of a surface of an optically transparent substrate such as a glass substrate (e.g., sodalime glass, float glass, borosilicate and low iron sodalime glass), plastic cover, acrylic Fresnel lense or other optically transparent substrate (Block 50). The AR coating solution is then cured to form an AR coating on the optically transparent substrate (Block 60). The AR coating solution may be applied to any portion of substrate, as well as on one or both sides of the substrate. The substrate may be pre-coated such that the AR coating solution is applied onto an existing coating layer.

The AR coating solution may be applied onto the optically transparent element by a variety of generally known coating methods including spin-on, slot die, spray, dip, roller and other coating techniques. The amount of solvent used to form the AR coating solution may result in a solids concentration ranging from about 1 to about 25 weight percent, more particularly, from about 1-10 weight percent, even more particularly, from about 1-5 weight percent depending upon the application method and/or performance requirements. In some embodiments, there may be manufacturing advantages to forming a more concentrated batch in the STR, followed by diluting to a desired concentration. In alternate embodiments, dilution could occur prior to or during the initial mixing stage. For dip coating, a solids concentration of about 10 to 20 weight percent may be suitable. For other coating methods such as spin, slot die and spray, a lower solids concentration of about 1 to 5 weight percent may be suitable. Embodiments of the present invention may be particularly suitable for spray application due to the relatively small polymer particle size of the fluoropolymer. The viscosity of the resulting coating solution may vary from between about 0.5 cP to greater than 500 cP, more particularly, from about 0.5 cP to about 10 cP, even more particularly from about 0.75 cP to about 2.0 cP.

After application, the applied AR coating solution is cured to form the optically transparent substrate (Block 60). When applied to glass substrates, the AR coating solution can be subjected to a low temperature heat curing step, ranging from about 75° C. to about 350° C., more particularly, from about 150° C. to about 325° C., even more particularly from about 200° C. to about 300° C. Curing may be carried out for between about 1 minute and about 1 hour, more particularly, from about 1 minute to about 15 minutes to cure the coatings. The resulting coating may be, according to certain embodiments, substantially non-porous.

In one embodiment, the AR coating solution is applied on a previously coated optically transparent substrate, for example, a sol gel or other anti-reflective material. Exemplary sol gel materials are described, for example in U.S. application Ser. No. 12/796,199, which is hereby incorporated by reference in its entirety. In other embodiments the AR coating solution is applied to at least a portion of both sides of the substrate.

AR coated optically transparent elements according to embodiments of the present invention may possess improved light transmittance characteristics. For example, the AR coating may have a refractive index in the range of about 1.3 (e.g., 1.25 to 1.35) and have up to about a 2.5 percent transmission gain (measured by a UV-Vis spectrometer) in the visible portion (350 to 1100 nanometers) of the light spectrum. If both sides of an optically transparent substrate are coated, up to about a 5 percent transmission gain in the visible portion of the light spectrum may be achieved. In some embodiments, the absolute gain in transmittance is independent of the coating methods used as long as the thickness of the AR film is tuned to the incident light wavelength (the AR film thickness is about ¼th the wavelength of the incident light).

Anti-soil properties are a particular feature of the coatings of the present invention. Due to the hydrophobic nature of exemplary coatings, soil does not build on the optically transparent elements to the same extent as uncoated glass. The result is that transmittance is maintained for a longer period of time without having to clean the glass surface.

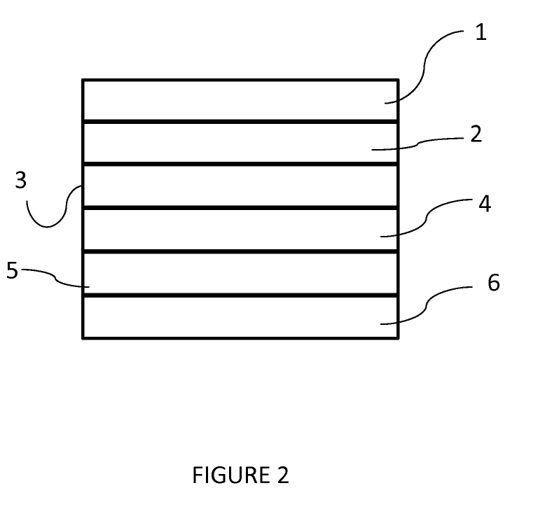

FIG. 2 is a cross-sectional view of a photovoltaic module (e.g., solar cell) for converting light to electricity, according to an embodiment of this invention. Incoming or incident light from the sun or the like is first incident on AR coating 1, passes therethrough and then through glass substrate 2 and front transparent electrode 3 before reaching the photovoltaic semiconductor (active film) 4 of the module. The module may also include, but does not require, a reflection enhancement oxide and/or EVA film 5, and/or a back metallic contact and/or reflector 6 as shown in FIG. 2. Other types of photovoltaic devices may of course be used, and the FIG. 2 module is merely provided for purposes of example and understanding. It will also be understood that a module may include a single AR coated optically transparent substrate that covers multiple photovoltaic cells connected in series.

As explained above, the AR coating 1 reduces reflections of the incident light and permits more light to reach the thin film semiconductor film 4 of the photovoltaic module thereby permitting the device to act more efficiently. While certain of the AR coatings 1 discussed above are used in the context of the photovoltaic devices/modules, this invention is not so limited. AR coatings according to this invention may be used in other applications. Also, other layer(s) may be provided on the glass substrate under the AR coating so that the AR coating is considered disposed on the glass substrate even if other layers are provided therebetween.

### Examples 1-5

### Polymerization of 2,3,3,3-tetrafluoro-1-propene (HFO-1234yf)

A pressure reactor was charged with 0.4 L of water, 2.58 g (9.64×10⁻³ mol) of sodium phosphate dibasic heptahydrate, 1.35 g (1.13×10⁻² mol) of sodium phosphate monobasic, 0.0148 g (5.32×10⁻⁵ mol) of ferrous sulfate heptahydrate, 4.80 g (0.011 mol) of ammonium perfluorooctonoate and 158.5 g (1.39 mol) of HFO-1234yf. The temperature of the reactor was raised to 80° C. followed by the constant addition of 40 mL of a 0.091 M solution of potassium persulfate over a 3 h period. After the addition of the persulfate was complete, the reaction was allowed to proceed for an additional 16 h at 80° C. The contents of the autoclave were then cooled to ambient temperature, transferred to a beaker and acidified with 12M HCl to induce precipitation of the polymer. The polymer was filtered and then washed with H₂O until the filtrate had a neutral pH. After drying, a total of 44.48 g of white polymer was isolated. (28.1% yield).

Example 2 was similar to Example 1 except that the initiator was added in one portion and the amount of monomer charged into the reactor was 148.6 g (1.3 mol). Yield of polymer obtained from this reaction was 90.2 g (60.7% yield).

Example 3 was similar to Experiment 1 except that the quantity of surfactant was decreased by 33% to 2.98 g (6.91×10⁻³ mol) and the quantity of monomer charged into the reactor was increased to 161 g (1.41 mol). The yield of polymer was 55.73 g (34.6% yield).

Example 4 was similar to Experiment 1, except that the reaction temperature was lowered to 55° C. and the quantity of monomer charged was decreased to 151.7 g (1.33 mol). The yield of polymer was 122.38 g (80.7% yield). It was evident from this experiment that polymerization is favored by a lower reaction temperature.

Example 5 was similar to Example 4 except that the surfactant was reduced by 33% and the quantity of monomer charged was increased to 178.9 g (1.57 mol). The yield of polymer obtained from this experiment was 166.71 g (93.2% yield). This experiment indicated that polymer formation is favored by lower reaction temperature (as above) and lower surfactant concentration.

### Example 6

### Preparation of Anti-Reflective Coatings

The fluoropolymer produced according to Example 5 was dissolved in ethyl acetate to form various anti-reflective coating solution samples each having polymer concentrations of about 3.5 wt %. For each Sample listed in Table 1 below, the resulting coating solutions were applied to a glass and a silicon wafer by spin coating at 1500 rpm for 35 seconds, and the coated wafers were then cured at various temperatures as indicated below. Sample 9 was a variation of Samples 1-8 in which the wafers were first coated with a 137 nm thick sol gel coating, and then a 20 nm thick coating of the fluoropolymer described herein was applied. The sol gel coating was formed by reacting tetraethoxy silane and methyltriethoxy silane in a 2:1 molar ratio in IPA in the presence of a tetrabutylammonium hydroxide (40% aq. solution) base catalyst. The reaction mixture was heated to 35-70° C. for 1-3.5 h, cooled and then nitric acid was added to the reaction mixture in a semi-batch fashion to adjust the pH of the reaction mixture to 0.5-1.7. The reaction mixture was then further cooled and diluted with organic solvent. The substrate was then coated and cured at 600-750° C. After curing, the fluoropolymer layer was applied.

TABLE 1

| | | Coating | | T | | | |
|---|---|---|---|---|---|---|---|
| | | Thickness | RI | gain | Contact | Film | Adhesion |
| Sample | Cure | (nm) | (550 nm) | (350-1000) | angle | Uniformity | Test |
| 1 | 300° C./5 min | 135 | 1.33 | 2.5 | 110 | Excellent | Good |
| 2 | 250° C./5 min | 147 | 1.34 | 2.3 | 107 | Excellent | Good |
| 3 | 200° C./5 min | 153 | 1.34 | 2.1 | 105 | Excellent | Good |
| 4 | 150° C./5 min | 157 | 1.34 | 1.9 | 105 | Good | Good |
| 5 | 100° C./5 min | 167 | 1.35 | 1.5 | 105 | Good | Poor |
| 6 | 80° C./5 min | 173 | 1.35 | 1.1 | 105 | Wet film | Poor |
| 7 | 300° C./5 min | 400 | 1.33 | 0 | 110 | Excellent | Good |
| 8 | 325° C./5 min | 400 | 1.33 | 0 | 110 | Excellent | Good |
| 9 | 325° C./5 min | 157 | 1.33 | 2.5 | 98 | Excellent | Good |

A broadband spectroscopy tool available from n&k Technology, Inc. was used for coating thickness measurements on the silicon wafers. The same tool was used for refractive index measurements. Transmittance was measured by UV-Visible spectral analysis measuring wavelengths from 300-2500 nm. The Adhesion Tape Test was used as an indicator of coating adhesion and was performed by forming cross-hatches in the coating (both at room temperature and after heating in boiling water), pressing an adhesive-backed tape material to the coated substrate, pulling the tape away from the coating and then studying the effect the tape had on the cross-hatched portions of the coating. The Contact Angle Test was used to determine the contact angle of the AR coated substrate using a VCA 2500 instrument available from AST Products, Inc. Film uniformity was analyzed visually using optical microscopy.

The result show that the AR coating of embodiments of the present invention improve light transmission (T gain) while maintaining coating uniformity and adhesion. Embodiments also demonstrate that the AR coatings can be cured at low temperatures compared to conventional sol gel coatings.

### Example 7

### Performance Testing

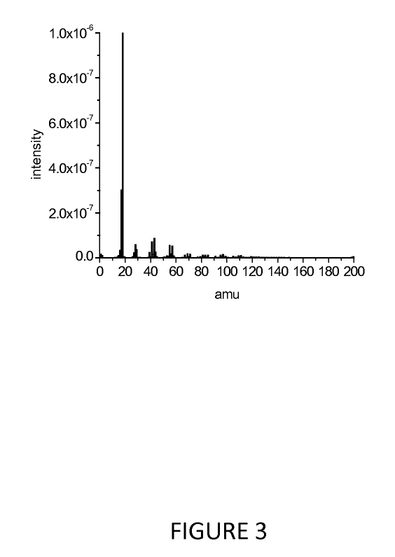

In addition to the test data shown in Table 1, several wafers were coated with a coating solution including an ethyl acetate solvent and 3.5 wt % fluoropolymer formed as described in Example 5 and having a molar weight of about 17,000 Daltons. The coating was cured at 300° C. and the resulting coating layer had a thickness of 140 nm. The resulting samples were subjected to various performance and durability tests. A thermal stability test was performed on single-side coated samples by measuring sample weight change at 300° C. over 170 minutes using differential scanning calorimetry. Average sample loss was only 0.81 wt % at the end of this period. Film out-gassing was measured by thermal desorption mass spectroscopy the results of which, as shown in FIG. 3, indicate beneficial out-gassing properties.

Transmittance performance was measured via an accelerated damp heat test at 130° C. and 85% relative humidity for 96 hours. Uncoated, single-side coated and double-side coated samples were all tested. Virtually no loss of transmittance was exhibited by the double-side coated samples, and only slight transmittance loss (≈0.3%) was exhibited by the single-side coated samples. In comparison, the uncoated samples exhibited significant transmittance loss (≈1.4%).

The anti-soil characteristics of the coating was measured by leaving a single-side coated sample (Sample 10) in an outdoor environment for 42 days and comparing transmittance loss and visual cleanliness to an uncoated glass substrate sample (Comparative Sample A) and a glass substrate sample coated with a 137 nm thick sol gel coating (Comparative Sample B). The sol gel coating was formed as described above with reference to Sample 9. The results set forth in Table 2 indicate that samples prepared according to embodiments of the present invention had anti-soil characteristics that were better than Comparative Samples A and B both in terms of visual appearance and light transmittance loss.

TABLE 2

| | | Transmittance at | |
|---|---|---|---|
| Sample | Days outside | 550 nm | Visual Appearance |
| Comparative | 0 | 90.8 | Clear |
| Sample A | 7 | 90.8 | Clear |
| | 14 | 90.3 | Clear |
| | 21 | 90.1 | Clear |
| | 28 | 89.3 | Dirty |
| | 35 | 88.1 | Dirty |
| | 42 | 87.4 | Dirty |
| Comparative | 0 | 94.9 | Clear |
| Sample B | 7 | 94.7 | Clear |
| | 14 | 94.9 | Clear |
| | 21 | 93.9 | Clear |
| | 28 | 94.0 | Clear |
| | 35 | 93.2 | Dirty |
| | 42 | 93.5 | Dirty |
| Sample 10 | 0 | 93.9 | Clear |
| | 7 | 93.8 | Clear |
| | 14 | 93.9 | Clear |
| | 21 | 94.0 | Clear |
| | 28 | 93.7 | Clear |
| | 35 | 93.5 | Clear |
| | 42 | 93.7 | Clear |

Various durability tests were also performed on Sample 10 as set forth in Table 3 below. All tests were passed.

TABLE 3

| Parameter | Test Conditions | Sample 10 |
|---|---|---|
| Salt spray test (DIN50021) | Heating in salt (5% NaCl) | Pass |
| | water at 35 C. for 2 min and | |
| | then in DI water for 1 min | |
| | up to 20 times | |
| Climate variable test | −40 C. to +85 C., 100 cycle | Pass |
| (IEC1215) | | |
| Damp test (IEC61250) | 130 C., 85% humidity, 96 h | Pass |
| Boiling DI water test | 100 C. for 30 min | Pass |
| Abrasion resistance (ISO- | Cheesecloth pad, 500 g | Pass |
| 9211-3-1-02) | weight, 200 rubs | |
| UV stability | Exposed under UV light @ | Pass |
| | 254 nm at room | |
| | temperature for 1 h | |
| Acid test (DIN50018) | 0.67% sulfuric/sulfurous | Pass |
| | acid, 40 C., 20 cycle of 2.5 min | |
| | each | |
| Base test | Same as acid test but with | Pass |
| | 0.67% aq. NaOH | |

### Examples 8-10

### Additional HFO Compounds

Example 8 is formed in a similar manner as Examples 1-5 except that HFO-1234zf is used in place of HFO-1234yf to form the polymer. Example 9 is formed in a similar manner as Examples 1-5 except that HFO-1234ze is used in place of HFO-1234yf to form the polymer. Example 10 is formed in a similar manner as Examples 1-5 except that HFO-1225 is used in place of HFO-1234yf to form the polymer. For each fluoropolymer, an anti-reflective coating is formed in the same manner as described in Example 6.

Various modifications and additions can be made to the exemplary embodiments discussed without departing from the scope of the present invention. For example, while the embodiments described above refer to particular features, the scope of this invention also includes embodiments having different combinations of features and embodiments that do not include all of the described features. Accordingly, the scope of the present invention is intended to embrace all such alternatives, modifications, and variations as fall within the scope of the claims, together with all equivalents thereof.

1. An optically transparent element comprising:
an optically transparent substrate; and
an anti-reflective coating disposed on a portion of at least one surface of the optically transparent substrate, the anti-reflective coating comprising at least one polymer represented by the formula: 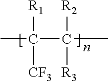
wherein n=10 to 2500, R₁, R₂ and R₃ are each selected from H and F and the polymer has a molecular weight between 2000 and 200,000 daltons.

2. The optically transparent element of claim 1 wherein the at least one polymer is represented by the formula: 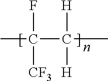
wherein n=15 to 2000.

3. The optically transparent element of claim 1 wherein the at least one polymer has a molecular weight between 10,000 and 100,000 daltons.

4. The optically transparent element of claim 1 wherein the at least one polymer is derived from a tetrafluoropropene or a pentafluoropropene compound.

5. The method of claim 4 wherein the compound is selected from the group consisting of HFO-1234yf, HFO-1234zf, HFO-1234ze, HFO-1225 and stereoisomers and combinations thereof.

6. The optically transparent element of claim 1 wherein the coating further comprises at least one additive.

7. The optically transparent element of claim 6 wherein the additive comprises a surfactant.

8. The optically transparent element of claim 1 wherein the coating comprises more than one layer.

9. The optically transparent element of claim 8 wherein at least an upper layer of the coating comprises the at least one polymer.

10. The optically transparent element of claim 8 wherein the coating comprises a lower layer comprising a sol gel and an upper layer comprising the at least one polymer.

11. The optically transparent element of claim 1 wherein the coating is disposed on at least a portion of a first surface and at least a portion of a second surface of the substrate.

12. The optically transparent element of claim 1 wherein the substrate comprises glass.

13. The optically transparent element of claim 1 consisting essentially of the at least one polymer.

14. A photovoltaic module comprising:
at least one semiconductor layer; and
the optically transparent element of claim 1.

15. A method of forming an optically transparent element comprising:
applying a coating solution onto at least a portion of a surface of an optically transparent substrate, the coating solution comprising at least one polymer represented by the formula: 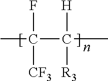
wherein n=10 to 2500, R₁, R₂ and R₃ are each selected from H and F and the polymer has a molecular weight between 2000 and 200,000 daltons; and
curing the coating solution to form an anti-reflective coating on the optically transparent substrate.

16. The method of claim 15 wherein the coating solution is applied by roller coating.

17. The method of claim 15 wherein the coating solution is cured at a temperature of less than 350° C.

18. The method of claim 15 wherein the coating solution is cured at a temperature of no more than about 300° C.

19. The method of claim 15 wherein the at least one polymer is represented by the formula: 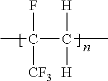
wherein n=15 to 2000.

20. The method of claim 15 wherein the at least one polymer is derived from a tetrafluoropropene or a pentafluoropropene compound.
